(19) United States
(12) Patent Application Publication
(10) Pub. No.: US 2016/0265104 A1
(43) Pub. Date: Sep. 15, 2016

(54) METHOD OF GROWING TWO-DIMENSIONAL CRYSTALS

(71) Applicant: NATIONAL CHUNG CHENG UNIVERSITY, Chia-Yi (TW)

(72) Inventors: YA-PING HSIEH, KAOHSIUNG CITY (TW); MARIO HOFMANN, Minxiong Township (TW); YI-JING CHIU, TAINAN CITY (TW)

(73) Assignee: NATIONAL CHUNG CHENG UNIVERSITY

(21) Appl. No.: 14/720,661

(22) Filed: May 22, 2015

(30) Foreign Application Priority Data
Mar. 9, 2015 (TW) 104107364

(51) Int. Cl. C23C 16/26; C23C 16/02; C01B 31/04; C23C 16/56

(52) U.S. Cl. CPC C23C 16/26; C23C 16/56; C23C 16/0272; C01B 31/0453

(57) ABSTRACT

A method of growing 2-D crystals includes: providing a plurality of sub-substrates; stacking the plurality of sub-substrates to form a stacked substrate; disposing the stacked substrate into a crystal-growing furnace; pumping a reaction gas into the crystal-growing furnace; and heating the crystal-growing furnace to enable the reaction gas to react on the stacked substrate, and at least one 2-D crystal is formed on at least one surface of the plurality of sub-substrates in the stacked substrate.

### CROSS-REFFERENCE TO RELATED APPLICATION

This application claims priority from Taiwan Patent Application No. 104107364, filed on Mar. 9, 2015, in Taiwan Intellectual Property Office, the contents of which are hereby incorporated by reference in their entirety for all purposes.

### BACKGROUND OF THE INVENTION

1. Field of the Invention

The exemplary embodiment(s) of the present invention relates to a field of a method of crystal-growing. More specifically, the exemplary embodiment(s) of the present invention relates to a method of growing 2-D crystals.

2. Description of Related Art

Graphene is a crystalline allotrope of carbon that its carbon atoms are densely packed into a 2-dimensional honeycomb lattice pattern, and is the basic structure element of all other dimensions of graphite materials. Graphene could be packaged into the zero-dimensional (0D) fullerenes, rolled as one-dimensional (1D) carbon nanotubes or stacked into three-dimensional (3D) graphite.

Graphene is current thinnest and the hardest nanomaterial in the world and it is almost completely transparent, only absorbing 2.3% of light. Graphene's thermal conductivity is high up to 5,300 W·m⁻¹·K⁻¹ larger than carbon nanotube and diamond. Graphene has electron mobility at room temperature that is over 15,000 cm²·V⁻¹·s⁻¹, which is higher than carbon nanotube or monocrystalline silicon, while merely has about 10⁻⁶ Ω·cm of resistivity, which is lower than copper or silver. Graphene is the smallest resistivity material at present in the world. Because of the low-resistance and fast electron mobility properties, thinner and higher conductivity of new generation electron elements or transistors could be developed. Since the graphene is essentially be a transparent, advantaged conductor, it is suitable for manufacturing transparent touch panels, display screens, LEDs, even solar cells.

The quality of the graphene decides the application. The better quality of graphene, the higher conductivity and carrier mobility. Therefore, enhancing the graphene's quality is the big issue in graphene application. In order to obtained high quality graphene, chemical vapor deposition (CVD) is widely-used in manufacturing higher quality graphene. Nevertheless, the mono lattice quality of the graphene depends on its growing time. The longer growing time, the better quality. Hence, the more advantaged quality of the graphene, much more costs and the prices and the quality is positive correlation so far. The most common way in graphene growing is to utilize variety of metal thin films, such as copper, nickel or substrates vapor deposited with metal thin films, on which the graphene is growing at high temperature. Therefore, the size of the graphene is limited to the size of the chamber.

The conventional method of growing 2-D crystals such as graphene is generally dispose the single substrate into the crystal-growing furnace, then pump into reaction gases, and make reaction gases react by heating and eventually form 2-D crystals on the substrate. Nevertheless, this method is constrained by many factors such as the disposition of the substrate, the size of the crystal-growing furnace, etc., resulted in the low efficiency of growing that dose not fit the demand of mass production nowadays. Therefore, it is needed a method that enable to mass-produce 2-D materials in the same growing time upon the condition without greatly change the present high temperature growing devices.

### SUMMARY OF THE INVENTION

In view of the shortcomings of the prior art, it is a primary objective of the present invention to provide a method of growing 2-D crystals to solve the problem that the single substrate-grown 2-D crystals cannot be mass production.

To achieve the aforementioned objective, the present invention provides a method of growing 2-D crystals, at least comprising: providing a plurality of sub-substrates; stacking the plurality of sub-substrates to form a stacked substrate; disposing the stacked substrate into a crystal-growing furnace; pumping a reaction gas into the crystal-growing furnace; and heating the crystal-growing furnace to enable the reaction gas to react on the stacked substrate, and at least one 2-D crystal is formed on at least one surface of the plurality of sub-substrates in the stacked substrate.

Preferably, a material of the plurality of sub-substrates is metal.

Preferably, the surface of the plurality of sub-substrates comprises an upper surface, a lower surface or a side surface.

Preferably, the plurality of sub-substrates are flat substrates.

Preferably, the plurality of sub-substrates is a flexible substrate. And the stacked substrate is formed as a rolled substrate in a form of a column by rolling-stacking the plurality of sub-substrates, wherein the column is a cylinder or a square column, and each of the plurality of sub-substrates is formed as the rolled substrate by rolling-stacking concentrically.

Preferably, the method of growing 2-D crystals of the present invention further comprises: disposing a separation layer between the plurality of sub-substrates, wherein, a material of the separation layer is sapphire, quartz, or mica. The separation layer is a flexible separation layer or an inflexible separation layer.

As above, the method of growing 2-D crystals in the preset invention has one ore more of the following advantages.

(1) The method of growing 2-D crystals of the present invention may increase the contact area during the 2-D crystal growth by stacking the plurality of sub-substrate as the stacked substrate or rolling the plurality of sub-substrate as the rolled substrate, to solve the problem that the way with single substrate grown 2-D crystals cannot be mass production.

(2) The method of growing 2-D crystals of the present invention may produce great amount of the crystal by conventional high temperature growing devices during the same time.

(3) The method of growing 2-D crystals of the present invention may prevent the substrate from sticking to each other due to melting or evaporating at high temperature by disposing the separation layer between each of the plurality of sub-substrates and then affect the whole quality of the 2-D crystal growth.

With these and other objects, advantages, and features of the invention that may become hereinafter apparent, the nature of the invention may be more clearly understood by reference to the detailed description of the invention, the embodiments and to the several drawings herein.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 illustrates a schematic diagram of a method of growing 2-D crystals in accordance with first embodiment of the present invention.

FIG. 2 illustrates a schematic diagram of a method of growing 2-D crystals in accordance with second embodiment of the present invention.

FIG. 3 illustrates a diagram of the first aspect of the plurality of sub-substrate which is a flat substrate in accordance with the present invention.

FIG. 4 illustrates a diagram of the first aspect of the plurality of sub-substrate which is a flexible substrate in accordance with the present invention.

FIG. 5 illustrates a diagram of the second aspect of the plurality of sub-substrate which is a flexible substrate in accordance with the present invention.

FIG. 6 illustrates a diagram of the plurality of sub-substrate which is a flat substrate in accordance with the second embodiment of the present invention.

FIG. 7 illustrates a diagram of the first aspect of the plurality of sub-substrate which is a flexible substrate in accordance with the second embodiment of the present invention.

FIG. 8 illustrates a diagram of the second aspect of the plurality of sub-substrate which is a flexible substrate in accordance with the second embodiment of the present invention.

FIG. 9 is a diagram illustrating the roll-to-roll crystal growing processing application of a method of growing 2-D crystals of the present invention.

### DETAILED DESCRIPTION OF THE PREFERRED EMBODIMENTS

Exemplary embodiments of the present invention are described herein in the context of a method of growing 2-D crystals

Those of ordinary skilled in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

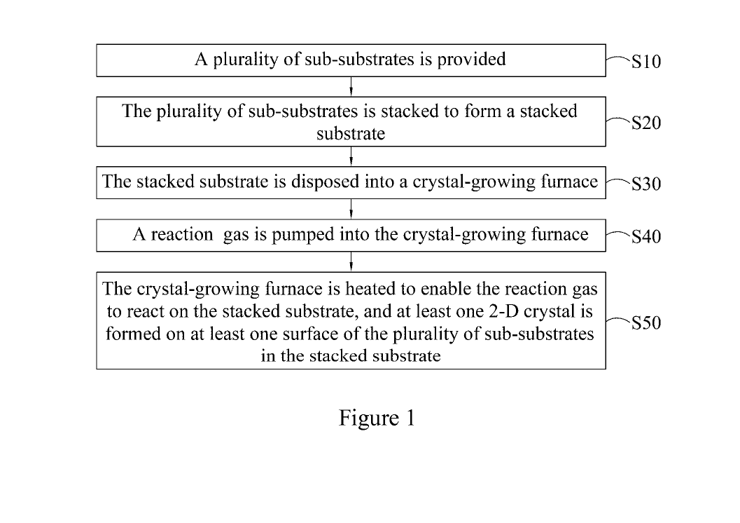

With reference to FIG. 1, this figure illustrates a schematic diagram of a method of growing 2-D crystals in accordance with first embodiment of the present invention. The method of growing 2-D crystals at least comprises steps S10 to S50. As shown in FIG. 1, at first, a plurality of sub-substrate is provided (step S10), then the plurality of sub-substrates is stacked to form a stacked substrate (step S20), and the stacked substrate is disposed into a crystal-growing furnace (step S30), then a reaction gas is pumped into the crystal-growing furnace (step S40), finally, the crystal-growing furnace is heated to enable the reaction gas to react on the stacked substrate, and at least one 2-D crystal is formed on at least one surface of the plurality of sub-substrates in the stacked substrate (step S50). Wherein, a material of the plurality of sub-substrates is metal, for example, copper, nickel, or platinum, etc.

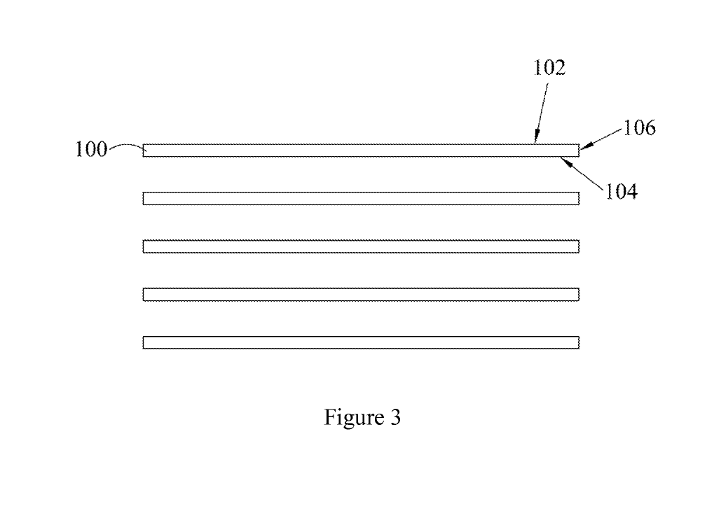

In the present invention, the plurality of sub-substrates may be a flat substrate. With reference to FIG. 3, this illustrates a diagram of the first aspect of the plurality of sub-substrate 100 which is a flat substrate in accordance with the present invention. The surface of the plurality of sub-substrates 100 comprises an upper surface 102, a lower surface 104 or a side surface 106, and the graphene 2-D crystal may be obtained by growing on the upper surface 102, the lower surface 104 or the side surface 106, even all surfaces of the plurality of sub-substrates 100. In addition, since 2-D crystals could grow on the surface of the plurality of sub-substrates 100 of the present invention, the spacing between each of the plurality of sub-substrates 100 may affect the quality of grown 2-D crystals.

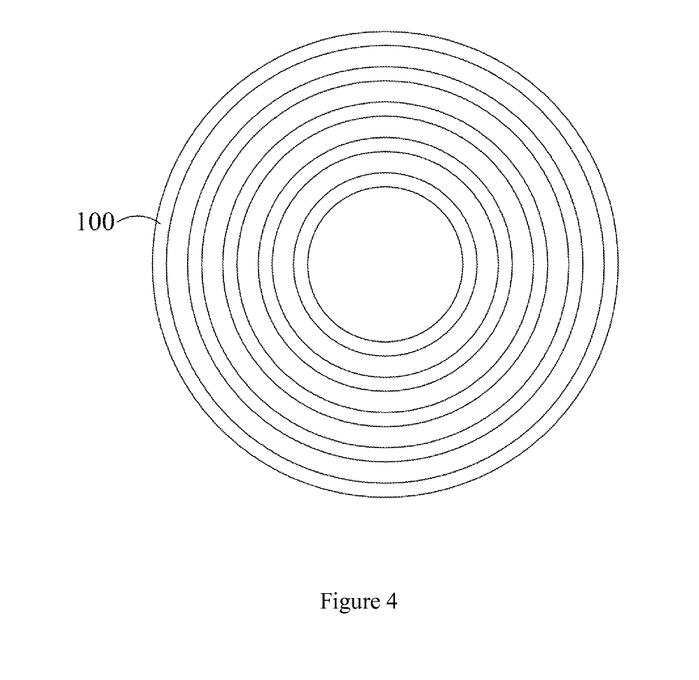

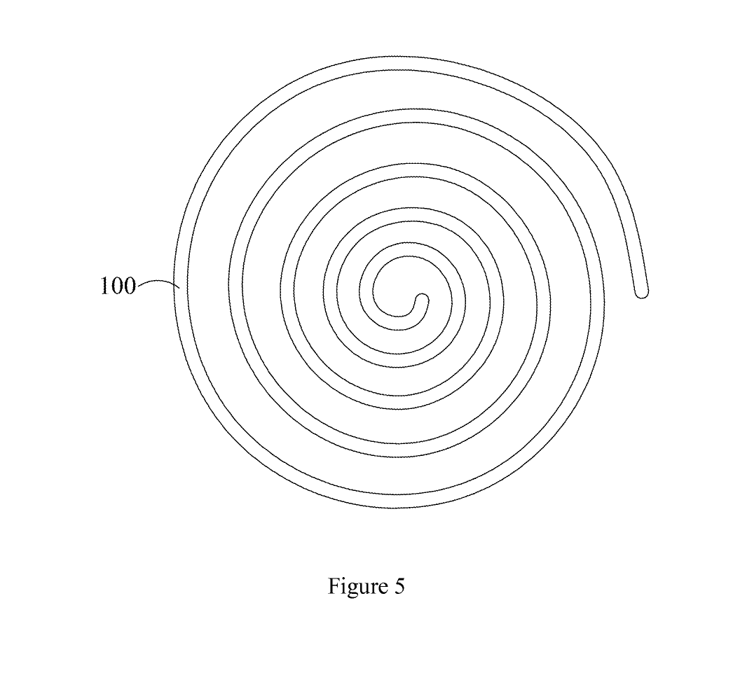

The plurality of sub-substrates may be a flexible substrate as well. With reference to FIG. 4 and FIG. 5. FIG. 4 illustrates a diagram of the first aspect of the plurality of sub-substrate 100 which is a flexible substrate in accordance with the present invention. FIG. 5 illustrates a diagram of the second aspect of the plurality of sub-substrate 100 which is a flexible substrate in accordance with the present invention. More detailed, as shown in FIG. 4, each of the plurality of sub-substrates 100 may be formed as the rolled substrate in shape of a column by rolling-stacking concentrically, wherein the column may be such as a cylinder (FIG. 4) or a square column (not shown). Alternatively, as shown in FIG. 5, a single sub-substrate 100 may also be formed as the rolled substrate by rolling-stacking The aforementioned fashion of the plurality of sub-substrates 100 is only exemplary not restrictive, any method of rolling the plurality of sub-substrates 100 is in the scope of the present invention claimed, and the skill in the art can modify the rolling way or stacking way of the plurality of sub-substrates 100 based on actual requirements.

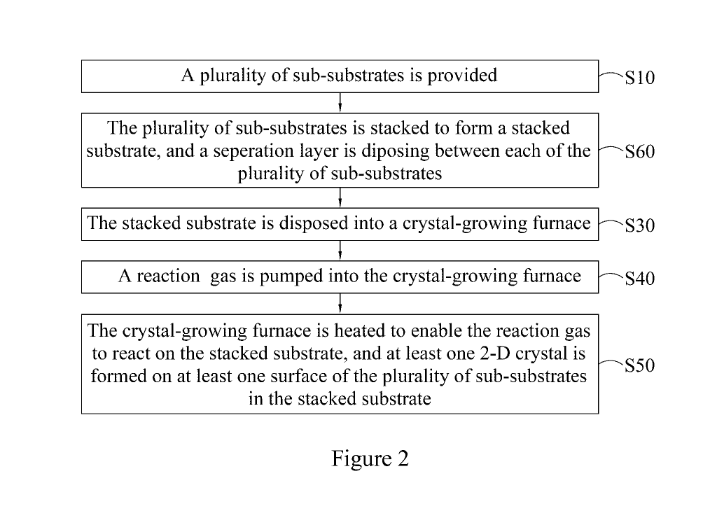

A separation layer can be further disposed between each of the plurality of sub-substrate, and its melting point is higher than the growing temperature of the 2-D crystal. Therefore, substrates that sticking to each other due to melting or evaporating of the plurality of sub-substrates when growing 2-D crystals at high temperature then affecting the whole quality of the 2-D crystal growth can be prevented. With continuously reference to FIG. 2, which is a schematic diagram of a method of growing 2-D crystals in accordance with second embodiment of the present invention. In the method of growing 2-D crystals of the present invention, the differences between second embodiment and aforementioned first embodiment is merely that the plurality of sub-substrates step is stacked into a stacked substrate and a separation layer is disposed between each of the plurality of sub-substrates in the step 60 of the second embodiment. In addition, since the separation layer itself could be as the parent material of growing 2-D crystals, for example, the graphene requires structure with carbon component (e.g. graphite flakes), it not only could be supplementary growing sources of 2-D crystals but also could make sure the plurality of sub-substrates without sticking to each other. A material of the separation layer may be solid materials such as sapphire, quartz, or mica, etc., with high melting points. The size of the separation layer may be the same as the plurality of sub-substrates or not.

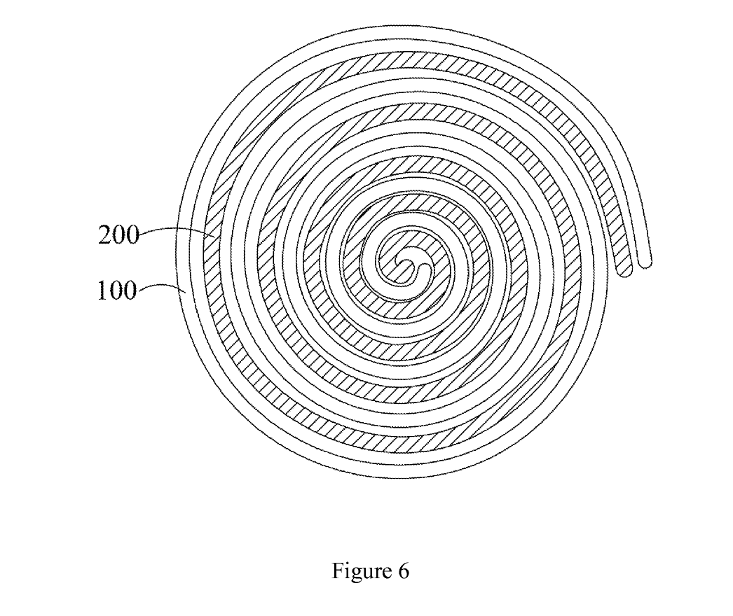

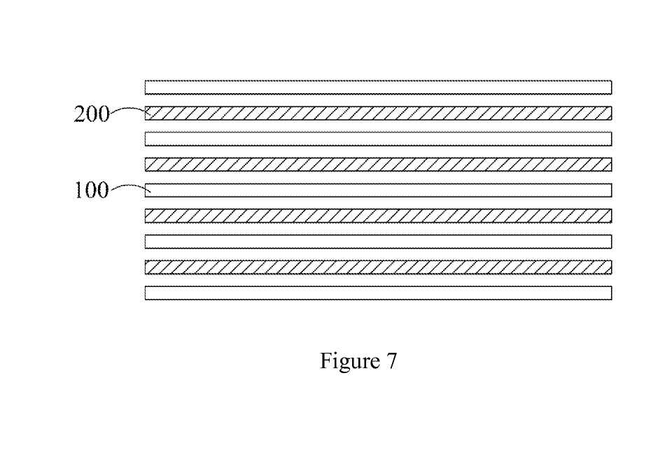

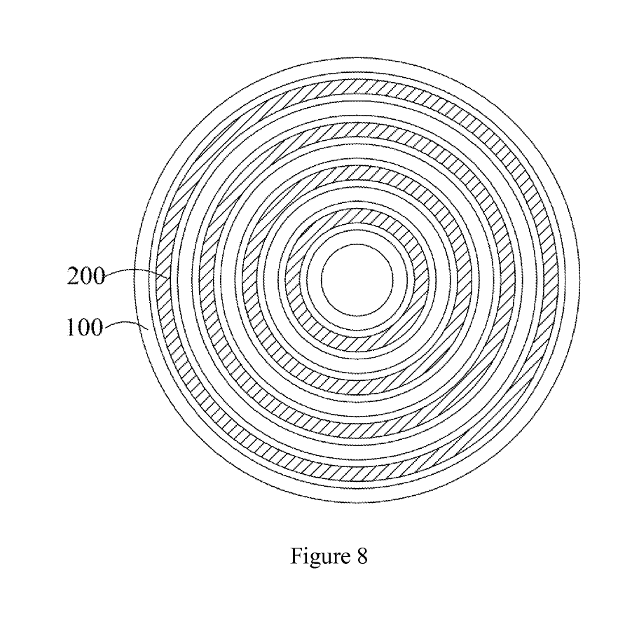

Alternatively, the separation layer may be a flexible separation layer or an inflexible separation layer. For example, as shown in FIGS. 6 to 8, FIG. 6 is a diagram of the plurality of sub-substrate which is a flat substrate in accordance with the second embodiment of the present invention; FIG. 7 is a diagram of the first aspect of the plurality of sub-substrate which is a flexible substrate in accordance with the second embodiment of the present invention; FIG. 8 is a diagram of the second aspect of the plurality of sub-substrate which is a flexible substrate in accordance with the second embodiment of the present invention. More specifically, a separation layer 200 may be disposed between each of the flat substrate (see FIG. 6, the size of the separation layer 200 is the same with the flat substrate), or be disposed between each of the flexible substrate (see FIG. 7, the separation layer 200 and the plurality of sub-substrate 100 are alternately arranged by concentric fashion), or further, the separation layer 200 may be disposed between the rolled single flexible substrate (see FIG. 8).

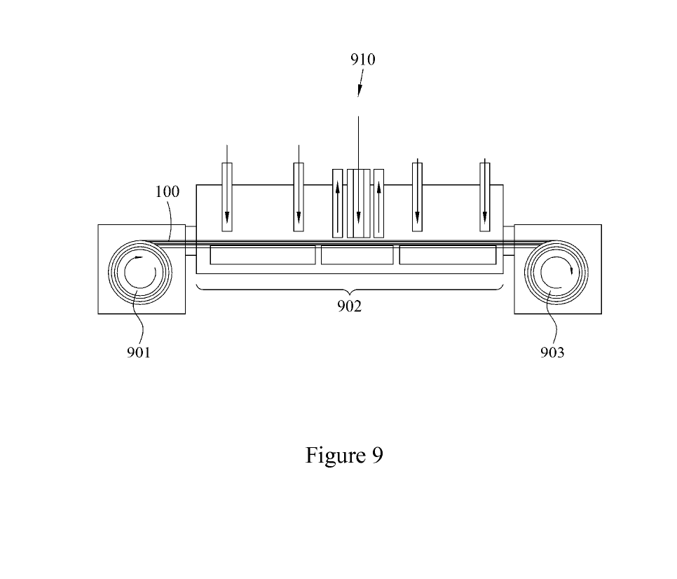

A Roll-to-Roll growing process may be applied to the method of growing 2-D crystals of present invention. With reference to FIG. 9, which is a diagram that illustrating the Roll-to-Roll crystal growing processing application of a method of growing 2-D crystals of the present invention. As shown in FIG. 9, take the plurality of sub-substrates 100 as copper substrates for example, when processing the growth of graphene 2-D crystals, the plurality of sub-substrates 100 could be deliver to the chemical vapor deposition region (CVD region 902) by the copper roller 901, so as to make the CVD reaction gas 910 react at the high temperature, and to form the graphene 2-D crystals on at least one (even all the) surface of the stacked plurality sub-substrates 100 (i.e. the stacked substrate), finally the graphene could be obtained from the other roller (see the graphene/copper roller 903 in FIG. 9). Compare to the conventional method, the method of growing 2-D crystals of present invention by stacking the plurality of sub-substrates may improve the growth efficiency effectively. Above description for the application of Roll-to-Roll crystal growing process in the method of growing 2-D crystals could be adjusted and modified based on practice requirements, and not be limited to the FIG. 9 or the aforementioned context.

From the abovementioned explanation, the method of growing 2-D crystals of the present invention, by stacking the plurality of sub-substrates to form the stacked substrate or rolling it to the rolled substrate, may increase the contact area during the 2-D crystal growth, then solve the problem that conventional method of which grows 2-D crystals with single substrate cannot mass produce 2-D crystals. In addition, the method of the present invention may grow the great amount of 2-D crystals costing the same time on the existing high temperature growing device. Furthermore, the method of the present invention may also prevent substrates from sticking to each other due to melting or evaporating of the plurality of sub-substrates when growing 2-D crystals at high temperature then affecting the whole quality of the 2-D crystal growth by disposing the separation layer between each of the plurality of sub-substrates.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

What is claimed is:

1. A method of growing 2-D crystals, comprising:
providing a plurality of sub-substrates;
stacking the plurality of sub-substrates to form a stacked substrate;
disposing the stacked substrate into a crystal-growing furnace;
pumping a reaction gas into the crystal-growing furnace; and
heating the crystal-growing furnace to enable the reaction gas to react on the stacked substrate, and at least one 2-D crystal is formed on at least one surface of the plurality of sub-substrates in the stacked substrate.

2. The method of claim 1, wherein a material of the plurality of sub-substrates is metal.

3. The method of claim 1, wherein the surface of the plurality of sub-substrates comprises an upper surface, a lower surface or a side surface.

4. The method of claim 1, wherein the plurality of sub-substrates are flat substrates.

5. The method of claim 1, wherein the plurality of sub-substrates is a flexible substrate.

6. The method of claim 5, wherein the stacked substrate is formed as a rolled substrate in shape of a column by rolling-stacking the plurality of sub-substrates.

7. The method of claim 6, wherein the column is a cylinder or a square column, and each of the plurality of sub-substrates is formed as the rolled substrate by rolling-stacking concentrically.

8. The method of claim 1, further comprising:
disposing a separation layer between the plurality of sub-substrates.

9. The method of claim 8, wherein a material of the separation layer is sapphire, quartz, or mica.

10. The method of claim 8, wherein the separation layer is a flexible separation layer or an inflexible separation layer.
